(19) United States
(12) Patent Application Publication
(10) Pub. No.: US 2025/0176107 A1
(43) Pub. Date: May 29, 2025

(54) SEMICONDUCTOR PACKAGE

(71) Applicant: Samsung Electronics Co., Ltd., Suwon-si (KR)

(72) Inventors: Chunghee LEE, Suwon-si (KR); Yunrae CHO, Suwon-si (KR)

(73) Assignee: Samsung Electronics Co., Ltd., Suwon-si (KR)

(21) Appl. No.: 18/882,102

(22) Filed: Sep. 11, 2024

(30) Foreign Application Priority Data
Nov. 29, 2023 (KR) 10-2023-0170032

(51) Int. Cl. H05K 1/11; H01L 23/00; H01L 23/31; H01L 25/065; H05K 1/18

(52) U.S. Cl. CPC H05K 1/116; H01L 23/3135; H01L 23/3142; H01L 24/16; H01L 24/32; H01L 24/73; H01L 25/0657; H05K 1/181; H01L 2224/16148; H01L 2224/16227; H01L 2224/32225; H01L 2224/73204; H01L 2225/06513; H01L 2225/06517; H01L 2225/06541; H01L 2225/06548; H01L 2924/15151

(57) ABSTRACT

A semiconductor package may include a wiring substrate, a semiconductor chip connected to the wiring substrate through internal solder balls, and a sealing layer sealing the semiconductor chip. The wiring substrate may include a core layer, an upper protective layer, and a lower protective layer. A central through region of the wiring substrate may define a central through hole that penetrates the upper protective layer, the core layer, and the lower protective layer. The sealing layer may include an underfill layer between the internal solder balls and a molding layer on side and upper surfaces of the semiconductor chip. The underfill layer may include a same material as the molding layer. The central through hole may not be filled with a material layer or a portion of the central through hole may include an additional underfill layer.

### CROSS-REFERENCE TO RELATED APPLICATION

This application is based on and claims priority under 35 U.S.C. § 119 to Korean Patent Application No. 10-2023-0170032, filed on Nov. 29, 2023, in the Korean Intellectual Property Office, the disclosure of which is incorporated by reference herein in its entirety.

### BACKGROUND

Inventive concepts relate to a semiconductor package, and more particularly, to a semiconductor package with improved reliability of a sealing layer (or an underfill layer).

A semiconductor package may electrically connect a semiconductor chip to the upper surface of a wiring substrate by internal solder balls and to an external device through a plurality of external solder balls formed on the lower surface of the wiring substrate. The semiconductor package may be completed by molding the semiconductor chip electrically connected to the wiring substrate with a sealing layer. In the semiconductor package, it may be difficult to reliably fill the sealing layer (or the underfill layer) between the internal solder balls on the wiring substrate.

### SUMMARY

Inventive concepts provide a semiconductor package with improved reliability of a sealing layer (or an underfill layer).

According to an embodiment of inventive concepts, a semiconductor package may include a wiring substrate including a core layer, an upper protective layer on an upper surface of the core layer, and a lower protective layer on a lower surface of the core layer, the wiring substrate including a central through region defining a central through hole that penetrates the upper protective layer, the core layer, and the lower protective layer at a central portion of the wiring substrate; a semiconductor chip on the wiring substrate and the central through region, the semiconductor chip being connected to the wiring substrate through a plurality of internal solder balls; and a sealing layer on the wiring substrate and sealing the semiconductor chip. The sealing layer may include an underfill layer and a molding layer. The underfill layer may be between the plurality of internal solder balls on the wiring substrate. The molding layer may be on side surfaces of the semiconductor chip and an upper surface of the semiconductor chip. The underfill layer may include a same material as the molding layer. The central through hole may be not filled with a material layer or the central through hole may include an additional underfill layer in a portion of the central through hole adjacent to the upper protective layer.

According to an embodiment of inventive concepts, a semiconductor package may include a wiring substrate including a core layer, an upper protective layer on an upper surface of the core layer, and a lower protective layer on a lower surface of the core layer, the wiring substrate including a central through region defining a central through hole that penetrates the upper protective layer, the core layer, and the lower protective layer at a central portion of the wiring substrate, the wiring substrate including a surrounding through region defining a surrounding through hole that penetrates the upper protective layer, the core layer, and the lower protective layer at a surrounding portion of the wiring substrate, the surrounding portion of the wiring substrate surrounding the central portion of the wiring substrate, and the surrounding through hole being filled with a material layer; a semiconductor chip on the wiring substrate, the central through region, and the surrounding through region, the semiconductor chip being connected to the wiring substrate through a plurality of internal solder balls; and a sealing layer on the wiring substrate and sealing the semiconductor chip. The sealing layer may include an underfill layer and a molding layer. The underfill layer may be between the plurality of internal solder balls on the wiring substrate. The molding layer may be on side surfaces of the semiconductor chip and an upper surface of the semiconductor chip. The underfill layer may include a same material as the molding layer. The central through hole may be not filled with the material layer.

According to an embodiment of inventive concepts, a semiconductor package may include a wiring substrate including a core layer, an upper protective layer on an upper surface of the core layer, a lower protective layer on a lower surface of the core layer, and upper wiring pads in the upper protective layer of the wiring substrate, the wiring substrate including a central through region defining a central through hole that penetrates the upper protective layer, the core layer, and the lower protective layer at a central portion of the wiring substrate, the wiring substrate including a surrounding through region defining a surrounding through hole that penetrates the upper protective layer, the core layer, and the lower protective layer at a surrounding portion of the wiring substrate, the surrounding portion surrounding the central portion of the wiring substrate, and the surrounding through hole being filled with a material layer; a plurality of semiconductor chips spaced apart from each other on the wiring substrate, the central through region, and the surrounding through region, the plurality of semiconductor chips including a lowermost semiconductor chip connected to the upper wiring pads of the wiring substrate through a plurality of internal solder balls; and a sealing layer on the wiring substrate and sealing the plurality of semiconductor chips, the sealing layer including an underfill layer and a molding layer, the underfill layer being between the plurality of internal solder balls connecting the lowermost semiconductor chip to the wiring substrate, the molding layer being on side surfaces of the plurality of semiconductor chips and upper surfaces of the plurality of semiconductor chips, and the underfill layer including a same material as the molding layer. The central through hole may be not filled with the material layer.

### BRIEF DESCRIPTION OF THE DRAWINGS

Embodiments of inventive concepts will be more clearly understood from the following detailed description taken in conjunction with the accompanying drawings in which:

FIG. 1 is a cross-sectional view for describing a semiconductor package according to an embodiment;

FIG. 2 is a cross-sectional view for describing a central through region of a wiring substrate of FIG. 1;

FIG. 3 is a cross-sectional view for describing a surrounding through region of the wiring substrate of FIG. 1;

FIG. 4 is a top view illustrating a wiring substrate included in a semiconductor package according to the technical ideas of inventive concepts;

FIG. 5 is a cross-sectional view for describing a wiring substrate included in a semiconductor package according to an embodiment;

FIG. 6 is a cross-sectional view for describing a wiring substrate included in a semiconductor package according to an embodiment;

FIGS. 7 to 9 are cross-sectional views for describing a method of manufacturing a semiconductor package according to the technical ideas of inventive concepts;

FIG. 10 is a cross-sectional view for describing a flow of a sealing material in a method of manufacturing a semiconductor package according to the technical ideas of inventive concepts;

FIG. 11 is a top view for describing a flow of a sealing material for each portion of a wiring substrate in a method of manufacturing a semiconductor package according to the technical ideas of inventive concepts;

FIG. 12 is a top view illustrating wiring layers, upper wiring pads, and an underfill layer on a wiring substrate of a semiconductor package according to technical ideas of inventive concepts;

FIG. 13 is a cross-sectional view for describing a semiconductor package according to an embodiment;

FIG. 14 is a top view schematically illustrating a package module using a semiconductor package according to an embodiment;

FIG. 15 is a block diagram schematically illustrating a memory card using a semiconductor package according to an embodiment; and

FIG. 16 is a block diagram schematically illustrating an electronic system using a semiconductor package according to an embodiment.

### DETAILED DESCRIPTION

Hereinafter, embodiments are described in detail with reference to the accompanying drawings. The embodiments below may be implemented individually or in combination. Therefore, the technical ideas of inventive concepts is not interpreted by being limited to one embodiment. In the embodiments, an order of first, second, and nth is to facilitate a description, and inventive concepts are not limited to the order.

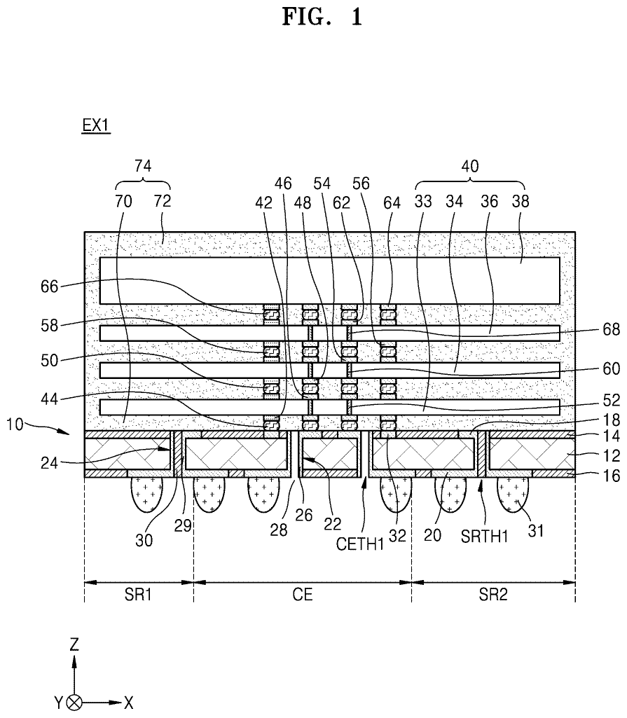

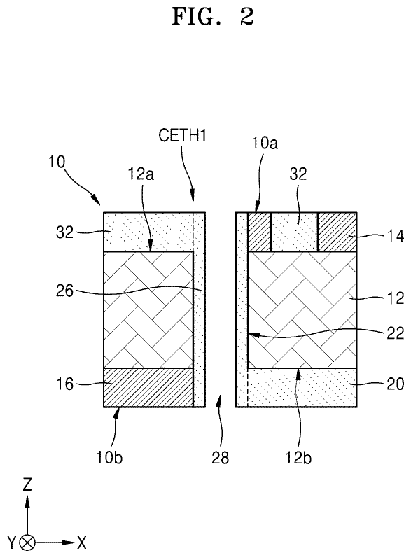

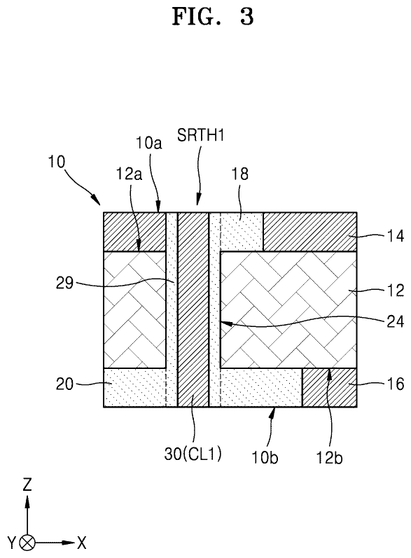

FIG. 1 is a cross-sectional view for describing a semiconductor package EX1 according to an embodiment, FIG. 2 is a cross-sectional view for describing a central through region CETH1 of a wiring substrate 10 of FIG. 1, and FIG. 3 is a cross-sectional view for describing a surrounding through region SRTH1 of the wiring substrate 10 of FIG. 1.

The semiconductor package EX1 may include the wiring substrate 10, the central through region CETH1, the surrounding through region SRTH1, semiconductor chips 40, and a sealing layer 74. FIGS. 1 to 3 may be cross-sectional views cut in a first direction (an X direction) and a third direction (a Z direction) with respect to an upper surface 10a (or the surface) of the wiring substrate 10. The third direction (the Z direction) may be a direction perpendicular to the upper surface 10a of the wiring substrate 10.

In some embodiments, the wiring substrate 10 may be a printed circuit board (PCB). The wiring substrate 10 may have the upper surface 10a and a lower surface 10b opposite to the upper surface 10a. The wiring substrate 10 may include a core layer 12, an upper protective layer 14 formed on an upper surface 12a of the core layer 12, and a lower protective layer 16 formed on a lower surface 12b of the core layer 12.

In some embodiments, the core layer 12 may include at least one of a prepreg resin, a thermosetting epoxy resin, a thermoplastic epoxy resin, and a filler-contained resin. In some embodiments, each of the upper protective layer 14 and the lower protective layer 16 may be a photosensitive resist (PSR) layer.

The wiring substrate 10 may further include a wiring layer 18 and upper wiring pads 32. The wiring layer 18 and the upper wiring pads 32 may be formed on the core layer 12. Although FIG. 1 shows only one wiring layer 18 at an upper portion of the wiring substrate 10, the wiring substrate 10 may include a plurality of wiring layers. For example, the wiring layer 18 may be formed even at an intermediate portion of the core layer 12 or on the lower surface 12b of the core layer 12.

The upper wiring pads 32 may be formed to be spaced apart from each other. Each of the wiring layer 18 and the upper wiring pads 32 may include a conductive material. Each of the wiring layer 18 and the upper wiring pads 32 may include a metal, e.g., copper (Cu) or aluminum (Al). The upper wiring pads 32 may be spaced apart from each other in the upper protective layer 14.

As shown in FIGS. 1 and 2, the central through region CETH1 may include a central through hole 22 penetrating the upper protective layer 14, the core layer 12, and the lower protective layer 16 in a central portion CE of the wiring substrate 10. The central through hole 22 may include an open region 28 not filled with a material layer.

In some embodiments, the central through hole 22 may not have the sealing layer 74 therein. In some embodiments, the sealing layer 74 may not be formed at a lower portion of the central through hole 22, i.e., at the lower surface 10b of the wiring substrate 10.

The central through region CETH1 may include a plurality of central through regions. For convenience, FIG. 1 shows two central through regions CETH1. Inventive concepts may include at least one central through region CETH1.

The central through hole 22 may penetrate between the upper surface 10a and the lower surface 10b of the wiring substrate 10. As described below, the central through hole 22 may be a through hole through which voids are to be discharged when an underfill layer 70 constituting the sealing layer 74 is formed.

A central via wiring layer 26 may be on the inner wall of the central through hole 22. The central via wiring layer 26 may be electrically connected to the wiring layer 18 and the upper wiring pads 32. The central via wiring layer 26 may be formed of a metal, e.g., Cu or Al.

As shown in FIGS. 1 and 3, the surrounding through region SRTH1 may include a surrounding through hole 24 penetrating the upper protective layer 14, the core layer 12, and the lower protective layer 16 in each of surrounding portions SR1 and SR2 of the wiring substrate 10.

The wiring substrate 10 may include two surrounding portions SR1 and SR2 in the cross-sectional view of FIG. 1. The surrounding through region SRTH1 may include a plurality of surrounding through regions in the surrounding portions SR1 and SR2.

The surrounding through hole 24 may include a closed region CL1 filled with a material layer 30. In some embodiments, the material layer 30 may include the same PSR layer as the upper protective layer 14 and the lower protective layer 16.

The surrounding through hole 24 may penetrate between the upper surface 10a and the lower surface 10b of the wiring substrate 10. The surrounding through hole 24 may insulate among the wiring layer 18, the upper wiring pads 32, and lower wiring pads 20.

A surrounding via wiring layer 29 may be on the inner wall of the surrounding through hole 24. The surrounding via wiring layer 29 may be electrically connected to the wiring layer 18 and the upper wiring pads 32. The surrounding via wiring layer 29 may be formed of the same material as that of the wiring layer 18 and the upper wiring pads 32. The surrounding via wiring layer 29 may be formed of a metal, e.g., Cu or Al.

The semiconductor chips 40 may be on the wiring substrate 10, the central through region CETH1, and the surrounding through region SRTH1. The semiconductor chips 40 may be on the wiring layer 18, the upper wiring pads 32, and the upper protective layer 14. The semiconductor chips 40 may include a first semiconductor chip 33, a second semiconductor chip 34, a third semiconductor chip 36, and a fourth semiconductor chip 38. In the present embodiment, although the semiconductor package EX1 includes four semiconductor chips 40, the semiconductor package EX1 may include only one semiconductor chip. The semiconductor chips 40 may be spaced apart from each other in the third direction (the Z direction).

The lower surfaces of the semiconductor chips 40 may be active surfaces on which a circuit layer is formed. First chip pads 42 and second chip pads 46 may be respectively on the lower surface and the upper surface of a central portion of the first semiconductor chip 33. Some of the first chip pads 42 may be connected to some of the second chip pads 46 through first vias 52, respectively. Third chip pads 48 and fourth chip pads 54 may be respectively on the lower surface and the upper surface of a central portion of the second semiconductor chip 34. Some of the third chip pads 48 may be connected to some of the fourth chip pads 54 through second vias 60, respectively.

Fifth chip pads 56 and sixth chip pads 62 may be respectively on the lower surface and the upper surface of a central portion of the third semiconductor chip 36. Some of the fifth chip pads 56 may be connected to some of the sixth chip pads 62 through third vias 68, respectively. Seventh chip pads 64 may be on the lower surface of a central portion of the fourth semiconductor chip 38.

First internal solder balls 44 respectively connected to the first chip pads 42 may be on the lower surface of the central portion of the first semiconductor chip 33 that is the lowermost semiconductor chip among the semiconductor chips 40. The first internal solder balls 44 may be electrically connected to internal wiring pads 32, respectively. Second internal solder balls 50 respectively connected to the second chip pads 46 and the third chip pads 48 may be on the lower surface of the central portion of the second semiconductor chip 34.

Third internal solder balls 58 respectively connected to the fourth chip pads 54 and the fifth chip pads 56 may be on the lower surface of the central portion of the third semiconductor chip 36. Fourth internal solder balls 66 respectively connected to the sixth chip pads 62 and the seventh chip pads 64 may be on the lower surface of the central portion of the fourth semiconductor chip 38.

The first to fourth internal solder balls 44, 50, 58, and 60 may include at least one metal or metal alloy among Cu, Al, nickel (Ni), silver (Ag), gold (Au), platinum (Pt), tin (Sn), lead (Pb), titanium (Ti), chromium (Cr), palladium (Pd), indium (In), and zinc (Zn).

The semiconductor chips 40 may include individual devices. The individual devices may include various microelectronic devices, e.g., a metal-oxide-semiconductor field effect transistor (MOSFET), such as a complementary metal-oxide-semiconductor (CMOS) transistor, a system large scale integration (LSI), an image sensor, such as a CMOS imaging sensor (CIS), a micro-electro-mechanical system (MEMS), an active device, a passive device, and the like.

In some embodiments, each of the semiconductor chips 40 may be a logic chip, a power management integrated circuit (PMIC) chip, or a memory chip. In some embodiments, the logic chip may be a memory controller chip, a central processing unit (CPU) chip, a graphics processing unit (GPU) chip, or an application processor (AP) chip.

In some embodiments, the memory chip may be a dynamic random access memory (DRAM) chip, a static random access memory (SRAM) chip, a flash memory chip, an electrically erasable and programmable read-only memory (EEPROM) chip, a phase-change random access memory (PRAM) chip, a magnetic random access memory (MRAM) chip, or a resistive random access memory (RRAM) chip.

The sealing layer 74 may seal the semiconductor chips 40 on the wiring substrate 10. The sealing layer 74 may include the underfill layer 70 filling between the first internal solder balls 44 on the wiring substrate 10 and a molding layer 72 on the side surfaces and the upper surfaces of the semiconductor chips 40. The central through region CETH1 may be located to correspond to the underfill layer 70. The sealing layer 74 may be referred to as a molded underfill layer. The underfill layer 70 and the molding layer 72 may be one body.

The sealing layer 74 may seal the semiconductor chips 40 without voids even between the first internal solder balls 44. The underfill layer 70 may be formed on the wiring substrate 10 without voids between the first internal solder balls 44. The sealing layer 74 may be formed on both side surfaces and the upper surfaces of the semiconductor chips 40 to seal the semiconductor chips 40.

The sealing layer 74 may be formed of, for example, a silicone-based material, a thermosetting material, a thermoplastic material, an ultraviolet (UV)-processed material, or the like. The sealing layer 74 may be formed of a polymer, such as a resin, or formed of, for example, an epoxy molding compound (EMC).

The lower wiring pads 20 insulated by the lower protective layer 16 and spaced apart from each other are beneath the wiring substrate 10. A plurality of external solder balls 31 are formed on the lower wiring pads 20, respectively. The lower wiring pads 20 may be formed of the same material as that of the upper wiring pads 32. The plurality of external solder balls 31 may be formed of the same material as that of the first to fourth internal solder balls 44, 50, 58, and 66.

As described above, the semiconductor package EX1 according to the technical ideas of inventive concepts may include the central through region CETH1 including at least one central through hole 22 at the central portion of the wiring substrate 10. The central through hole 22 may be an open region in which no material layer is formed. The semiconductor package EX1 according to the technical ideas of inventive concepts may be easily filled with the underfill layer 70 on the upper surface 10a of the wiring substrate 10 and between the first internal solder balls 44 on the wiring substrate 10 without voids. Accordingly, the semiconductor package EX1 according to inventive concepts may have improved reliability of the sealing layer 74 (the underfill layer 70 or the molding layer 72).

In addition, the semiconductor package EX1 according to the technical ideas of inventive concepts may include the surrounding through region SRTH1 including at least one surrounding through hole 24 in the surrounding portions SR1 and SR2 of the wiring substrate 10. The surrounding through hole 24 may be the closed region CL1 filled with the material layer 30. Accordingly, in the semiconductor package EX1 according to the technical ideas of inventive concepts, the wiring layer 18, the upper wiring pads 32, and the lower wiring pads 20 may be easily insulated from each other.

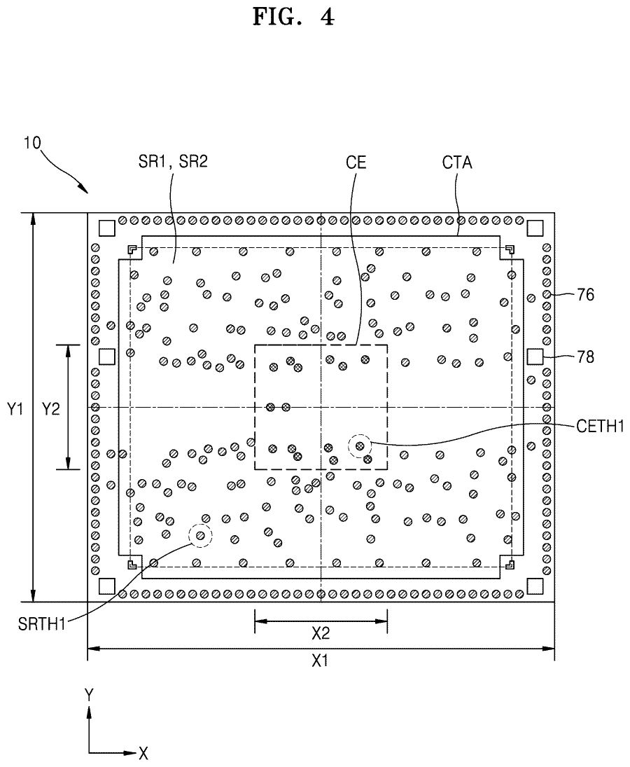

FIG. 4 is a top view illustrating a wiring substrate included in a semiconductor package according to the technical ideas of inventive concepts.

Particularly, FIG. 4 shows the wiring substrate 10 included in the semiconductor package EX1 of FIGS. 1 to 3. In FIG. 4, the description made with reference to FIGS. 1 to 3 is simply repeated or omitted.

The wiring substrate 10 may include the central portion CE and the surrounding portions SR1 and SR2 surrounding the central portion CE. The wiring substrate 10 may have a first length X1 and a second length Y1 in the first direction (the X direction) and a second direction (a Y direction), respectively. The first length X1 may be greater than the second length Y1. The first length X1 and the second length Y1 may be several mm to tens of mm.

The central portion CE of the wiring substrate 10 may have a third length X2 and a fourth length Y2 in the first direction (the X direction) and the second direction (the Y direction), respectively. The third length X2 may be the same as the fourth length Y2. The third length X2 and the fourth length Y2 may be several mm. In some embodiments, the area of the central portion CE with respect to the total area of the wiring substrate 10 may be about 10% to about 20%.

The wiring substrate 10 may have central through regions CETH1 in the central portion CE. The central through regions CETH1 may be the same as described with reference to FIG. 2. The central through regions CETH1 may be randomly arranged in the central portion CE in a top view.

The wiring substrate 10 may have surrounding through regions SRTH1 in the surrounding portions SR1 and SR2. The surrounding through regions SRTH1 may be the same as described with reference to FIG. 3. The surrounding through regions SRTH1 may be randomly arranged in the surrounding portions SR1 and SR2 in a top view.

The wiring substrate 10 may include a mounting region CTA of the semiconductor chips 40. Alignment patterns 78 for facilitating mounting of the semiconductor chips 40 may be located near the edge of the wiring substrate 10. Metal patterns 76 for discharging heat generated by the semiconductor chips 40 to the outside may be included near the edge of the wiring substrate 10.

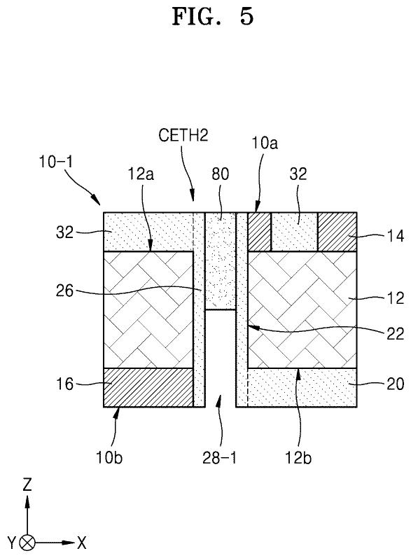

FIG. 5 is a cross-sectional view for describing a wiring substrate 10-1 included in a semiconductor package according to an embodiment.

Particularly, the wiring substrate 10-1 of FIG. 5 may be included in the semiconductor package EX1 of FIG. 1. The wiring substrate 10-1 of FIG. 5 may be the same as the wiring substrate 10 of FIG. 2 except that the wiring substrate 10-1 further includes an additional underfill layer 80 partially arranged in the open region 28 of the central through hole 22. In FIG. 5, the description made with reference to FIGS. 1 to 4 is simply repeated or omitted.

The wiring substrate 10-1 may have the upper surface 10a and the lower surface 10b opposite to the upper surface 10a. The wiring substrate 10-1 may include the core layer 12, the upper protective layer 14 formed on the upper surface 12a of the core layer 12, and the lower protective layer 16 formed on the lower surface 12b of the core layer 12. The wiring layer 18 (see FIG. 1) or the upper wiring pads 32 may be formed on the upper surface 12a of the core layer 12. The lower wiring pads 20 may be formed on the lower surface 12b of the core layer 12.

The wiring substrate 10-1 may include a central through region CETH2. The central through region CETH2 may include the central through hole 22 penetrating the upper protective layer 14, the core layer 12, and the lower protective layer 16 in the central portion CE (see FIG. 1) of the wiring substrate 10-1.

The central through hole 22 may penetrate between the upper surface 10a and the lower surface 10b of the wiring substrate 10-1. As described below, the central through hole 22 may be a through hole through which voids are to be discharged when the underfill layer 70 (see FIG. 1) constituting the sealing layer 74 (see FIG. 1) is formed.

The central through hole 22 may include an open region 28-1 partially filled with the additional underfill layer 80. The additional underfill layer 80 may be formed of the same material as that of the underfill layer 70 (see FIG. 1) described above.

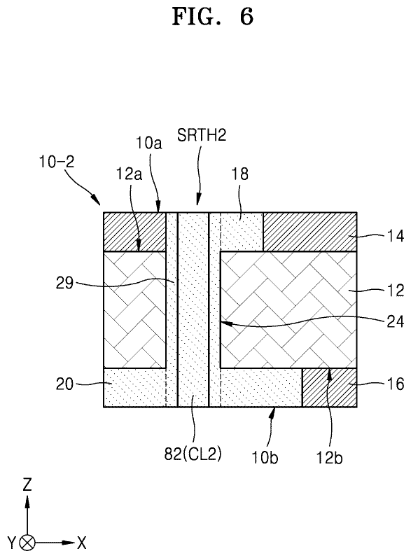

FIG. 6 is a cross-sectional view for describing a wiring substrate 10-2 included in a semiconductor package according to an embodiment.

Particularly, the wiring substrate 10-2 of FIG. 6 may be included in the semiconductor package EX1 of FIG. 1. The wiring substrate 10-2 may be the same as the wiring substrate 10 of FIG. 3 except that the surrounding via wiring layer 29 of the surrounding through hole 24 is filled with a material layer 82. In FIG. 6, the description made with reference to FIGS. 1 to 4 is simply repeated or omitted.

The wiring substrate 10-2 may have the upper surface 10a and the lower surface 10b opposite to the upper surface 10a. The wiring substrate 10-2 may include the core layer 12, the upper protective layer 14 formed on the upper surface 12a of the core layer 12, and the lower protective layer 16 formed on the lower surface 12b of the core layer 12. The wiring layer 18 or the upper wiring pads 32 (see FIG. 1) may be formed on the upper surface 12a of the core layer 12. The lower wiring pads 20 may be formed on the lower surface 12b of the core layer 12.

The wiring substrate 10-2 may include a surrounding through region SRTH2. The surrounding through region SRTH2 may include the surrounding through hole 24 penetrating the upper protective layer 14, the core layer 12, and the lower protective layer 16 in the surrounding portions SR1 and SR2 (see FIG. 1) of the wiring substrate 10-2.

The surrounding through hole 24 may penetrate between the upper surface 10a and the lower surface 10b of the wiring substrate 10-2. The surrounding through hole 24 may insulate among the wiring layer 18, the upper wiring pads 32 (see FIG. 1), and the lower wiring pads 20.

The surrounding via wiring layer 29 may be on the inner wall of the surrounding through hole 24. The surrounding through hole 24 may include a closed region CL2 filled with the material layer 82. In some embodiments, the material layer 82 may include the same metal layer as the surrounding via wiring layer 29.

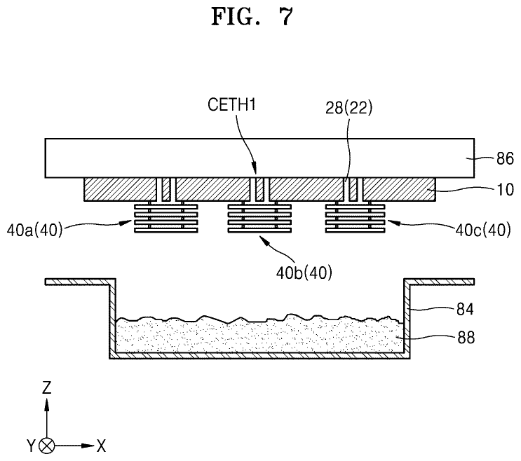

FIGS. 7 to 9 are cross-sectional views for describing a method of manufacturing a semiconductor package according to the technical ideas of inventive concepts.

Particularly, FIGS. 7 to 9 are provided to describe a method of manufacturing the semiconductor package EX1 of FIG. 1, in particular, to describe the sealing layer 74 (see FIG. 1). In addition, FIGS. 7 to 9 are provided to describe the central through region CETH1 of the semiconductor package EX1 of FIG. 1. In FIGS. 7 to 9, the description made with reference to FIGS. 1 to 4 is simply repeated or omitted.

Referring to FIG. 7, the central through region CETH1 is formed in the wiring substrate 10. The central through region CETH1 may include the central through hole 22 as described above. The central through hole 22 may include the open region 28 not filled with a material layer. The surrounding through region SRTH1 (see FIG. 1) may be formed in the wiring substrate 10 as described above but is omitted in FIG. 7 for convenience.

Semiconductor chip laminates 40a, 40b, and 40c are mounted on the wiring substrate 10. The semiconductor chip laminates 40a, 40b, and 40c may be on the wiring substrate 10 to be spaced apart from each other. Each of the semiconductor chip laminates 40a, 40b, and 40c may include the semiconductor chips 40 described above.

The wiring substrate 10 having the semiconductor chip laminates 40a, 40b, and 40c mounted thereon is upside down and disposed between a lower mold 84 and an upper mold 86. The lower mold 84 and the upper mold 86 may be referred to as a lower jig for sealing (or molding) and an upper jig for sealing (or molding), respectively. A sealing material 88, e.g., an EMC, may be contained inside the lower mold 84. The sealing material 88 may have a powder type.

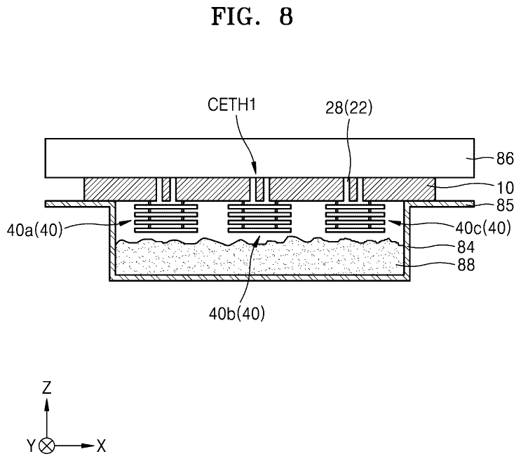

Referring to FIG. 8, the lower mold 84 or the upper mold 86 is moved upward and downward such that the wiring substrate 10 having the semiconductor chip laminates 40a, 40b, and 40c mounted thereon is in close contact with a clamp portion 85 connected to the lower mold 84. Then, the semiconductor chip laminates 40a, 40b, and 40c may be located inside the lower mold 84.

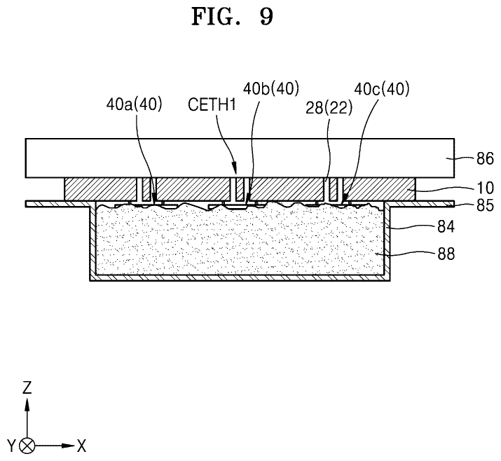

Referring to FIG. 9, the sealing layer 74 (see FIG. 1) covering the semiconductor chip laminates 40a, 40b, and 40c mounted on the wiring substrate 10 is formed by applying heat to the sealing material 88 while applying pressure between the lower mold 84 and the upper mold 86. Heat of about 100° C. to about 200° C. may be applied to the sealing material 88 between the lower mold 84 and the upper mold 86.

The sealing material 88 may be pressed between the lower mold 84 and the upper mold 86 and changed from a solid phase to a liquid phase (or a fluid phase) by the heat to seal the semiconductor chip laminates 40a, 40b, and 40c. The sealing material 88 changed to the liquid phase (or the fluid phase) may become the sealing layer 74 (see FIG. 1) of the solid phase with time.

The semiconductor chip laminates 40a, 40b, and 40c mounted on the wiring substrate 10 are individualized. In other words, the semiconductor chips 40 mounted on the wiring substrate 10 and the sealing layer 74 sealing the semiconductor chips 40 may be formed as shown in FIG. 1 by cutting the wiring substrate 10 for each of the semiconductor chip laminates 40a, 40b, and 40c.

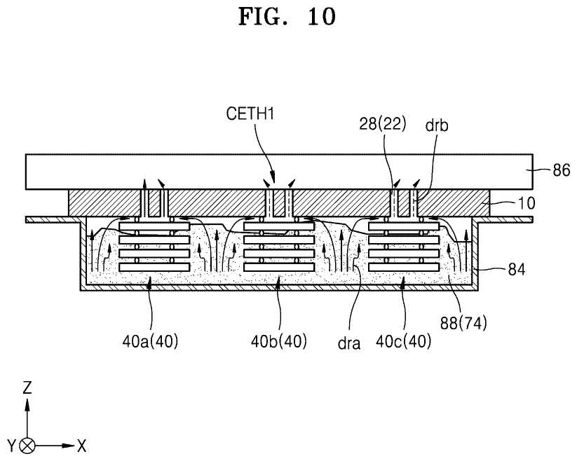

FIG. 10 is a cross-sectional view for describing a flow of the sealing material 88 in a method of manufacturing a semiconductor package according to the technical ideas of inventive concepts.

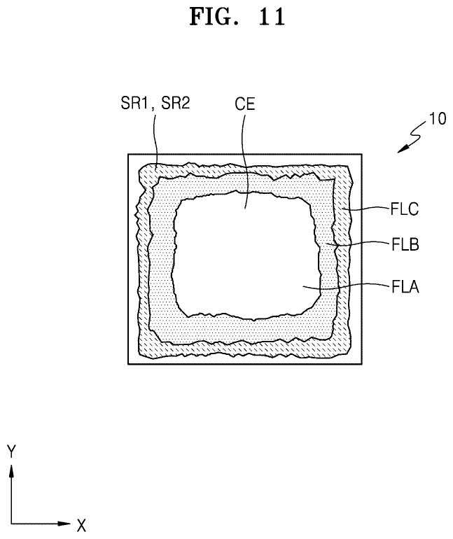

Particularly, FIG. 11 is provided to describe a flow of the sealing material 88 in the method of FIGS. 8 and 9 of manufacturing a semiconductor package. In FIG. 10, the description made with reference to FIGS. 8 and 9 is simply repeated or omitted. As shown in FIG. 10, the wiring substrate 10 having the semiconductor chip laminates 40a, 40b, and 40c mounted thereon are between the lower mold 84 and the upper mold 86.

In addition, as described above, the sealing material 88 may be pressed between the lower mold 84 and the upper mold 86 and changed from the solid phase to the liquid phase (or the fluid phase) by the heat to seal the semiconductor chip laminates 40a, 40b, and 40c. The semiconductor chip laminates 40a, 40b, and 40c may be immersed in the sealing material 88 of the liquid phase (or the fluid phase) inside the lower mold 84.

The sealing material 88 of the liquid phase (or the fluid phase) may move in the direction from the top semiconductor chips of the semiconductor chip laminates 40a, 40b, and 40c to the wiring substrate 10 as indicated by a reference sign dra.

In addition, voids (or air bubbles) generated in a process in which the sealing material 88 of the solid phase is changed to the sealing material 88 of the liquid phase (or the fluid phase) may be discharged through the open region 28 of the central through hole 22 of the wiring substrate 10 as indicated by a reference sign drb. The central through hole 22 may be a through hole for discharging voids when the sealing layer 74 (see FIG. 1) is formed. Accordingly, no voids may be generated in the sealing layer 74, in particular, the underfill layer 70 (see FIG. 1), of the semiconductor package EX1 (see FIG. 1) according to inventive concepts.

FIG. 11 is a top view for describing a flow of a sealing material for each portion of a wiring substrate in a method of manufacturing a semiconductor package according to the technical ideas of inventive concepts.

Particularly, FIG. 11 is provided to describe a flow rate of the sealing material 88 of the liquid phase (or the fluid phase) on the wiring substrate 10 when sealing of the semiconductor chip laminates 40a, 40b, and 40c is performed in the method of FIGS. 8 and 9 of manufacturing a semiconductor package. In FIG. 11, the description made with reference to FIGS. 8 and 9 is simply repeated or omitted.

As shown in FIG. 11, the wiring substrate 10 may include the central portion CE and the surrounding portions SR1 and SR2 surrounding the central portion CE. When the semiconductor chip laminates 40a, 40b, and 40c (see FIGS. 8 and 9) are sealed, in the central portion CE, the sealing material 88 (see FIGS. 8 and 9) of the liquid phase (or the fluid phase) may have a first flow rate FLA.

When the semiconductor chip laminates 40a, 40b, and 40c (see FIGS. 8 and 9) are sealed, in the surrounding portions SR1 and SR2, the sealing material 88 (see FIGS. 8 and 9) of the liquid phase (or the fluid phase) may have a second flow rate FLB and a third flow rate FLC.

The first flow rate FLA of the sealing material 88 (see FIGS. 8 and 9) in the central portion CE may be less than each of the second and third flow rates FLB and FLC of the sealing material 88 (see FIGS. 8 and 9) in the surrounding portions SR1 and SR2. The second flow rate FLB of the sealing material 88 (see FIGS. 8 and 9) in the surrounding portions SR1 and SR2 may be less than the third flow rate FLC of the sealing material 88 (see FIGS. 8 and 9) in the surrounding portions SR1 and SR2.

Accordingly, as described above, by preparing the central through hole 22 (see FIGS. 8 and 9) having the open region 28 (see FIGS. 8 and 9) in the central portion CE of the wiring substrate 10, the first flow rate FLA may increase to correspond to the second flow rate FLB and the third flow rate FLC of the sealing material 88 (see FIGS. 8 and 9).

Accordingly, as described above, the semiconductor package EX1 (see FIG. 1) according to inventive concepts may suppress the generation of voids in the sealing layer 74 (see FIG. 1), in particular, the underfill layer 70 (see FIG. 1), sealing the semiconductor chips 40 (see FIG. 1) mounted on the wiring substrate 10.

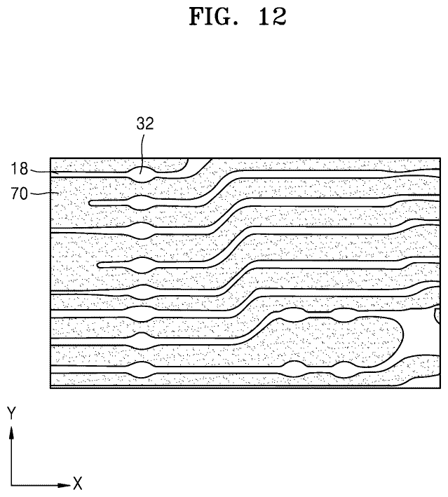

FIG. 12 is a top view illustrating wiring layers, upper wiring pads, and an underfill layer on a wiring substrate of a semiconductor package according to technical ideas of inventive concepts.

In particular, FIG. 12 shows wiring layers 18, the upper wiring pads 32, and the underfill layer 70 on the wiring substrate 10 of the semiconductor package EX1 of FIG. 1. The wiring layers 18 may extend in the first direction (the X direction) and be spaced apart from each other in the second direction (the Y direction).

The upper wiring pads 32 are electrically connected to the wiring layers 18. In some embodiments, the upper wiring pads 32 may be spaced apart from each other and aligned in the second direction (the Y direction). In some embodiments, the upper wiring pads 32 may be spaced apart from each other in the first direction (the X direction).

The underfill layer 70 may insulate between the wiring layers 18. The underfill layer 70 may insulate between the upper wiring pads 32. As described above, no voids may be generated in the underfill layer 70 between the wiring layers 18 and between the upper wiring pads 32.

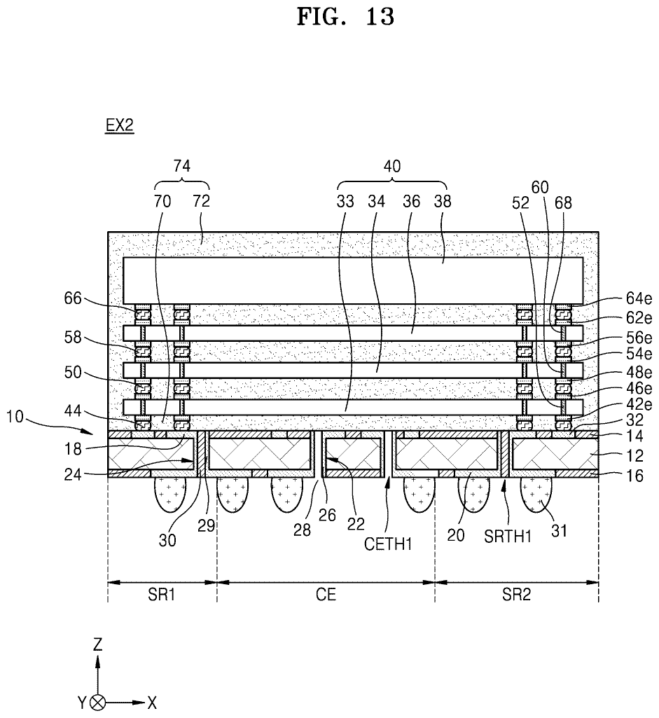

FIG. 13 is a cross-sectional view for describing a semiconductor package EX2 according to an embodiment.

Particularly, the semiconductor package EX2 may be the same as the semiconductor package EX1 of FIG. 1 except that the chip pads 44, 50, 58, and 66 of the semiconductor chips 40 are on an edge portion of the wiring substrate 10. In FIG. 13, the description made with reference to FIG. 1 is simply repeated or omitted.

The semiconductor package EX2 may include the wiring substrate 10, the central through region CETH1, the surrounding through region SRTH1, the semiconductor chips 40, and the sealing layer 74. The wiring substrate 10 may include the core layer 12, the upper protective layer 14 formed on the upper surface 12a of the core layer 12, and the lower protective layer 16 formed on the lower surface 12b of the core layer 12. The wiring substrate 10 may further include the wiring layer 18 and the upper wiring pads 32.

The central through region CETH1 may include the central through hole 22 penetrating the upper protective layer 14, the core layer 12, and the lower protective layer 16 in the central portion CE of the wiring substrate 10. The surrounding through region SRTH1 may include the surrounding through hole 24 penetrating the upper protective layer 14, the core layer 12, and the lower protective layer 16 in the surrounding portions SR1 and SR2 of the wiring substrate 10. The surrounding through hole 24 may be filled with the material layer 30.

The semiconductor chips 40 may be on the wiring substrate 10, the central through region CETH1, and the surrounding through region SRTH1. The semiconductor chips 40 may include the first semiconductor chip 33, the second semiconductor chip 34, the third semiconductor chip 36, and the fourth semiconductor chip 38.

First chip pads 42e and second chip pads 46e may be respectively on the lower surface and the upper surface of an edge portion of the first semiconductor chip 33. The first chip pads 42 may be connected to the second chip pads 46 through the first vias 52, respectively. Third chip pads 48e and fourth chip pads 54e may be respectively on the lower surface and the upper surface of an edge portion of the second semiconductor chip 34. The third chip pads 48e may be connected to the fourth chip pads 54e through the second vias 60, respectively.

Fifth chip pads 56e and sixth chip pads 62e may be respectively on the lower surface and the upper surface of an edge portion of the third semiconductor chip 36. The fifth chip pads 56e may be connected to the sixth chip pads 62e through the third vias 68, respectively. Seventh chip pads 64e may be on the lower surface of an edge portion of the fourth semiconductor chip 38.

The first internal solder balls 44 respectively connected to the first chip pads 42e may be on the lower surface of the edge portion of the first semiconductor chip 33 that is the lowermost semiconductor chip among the semiconductor chips 40. The first internal solder balls 44 may be electrically connected to the internal wiring pads 32, respectively. The second internal solder balls 50 respectively connected to the second chip pads 46e and the third chip pads 48e may be on the lower surface of the edge portion of the second semiconductor chip 34.

The third internal solder balls 58 respectively connected to the fourth chip pads 54e and the fifth chip pads 56e may be on the lower surface of the edge portion of the third semiconductor chip 36. The fourth internal solder balls 66 respectively connected to the sixth chip pads 62e and the seventh chip pads 64e may be on the lower surface of the edge portion of the fourth semiconductor chip 38.

The sealing layer 74 may seal the semiconductor chips 40 on the wiring substrate 10. The sealing layer 74 may include the underfill layer 70 filling between the first internal solder balls 44 on the wiring substrate 10 and the molding layer 72 on the side surfaces and the upper surfaces of the semiconductor chips 40. The sealing layer 74 may be referred to as a molded underfill layer. The underfill layer 70 and the molding layer 72 may be one body.

The sealing layer 74 may seal the semiconductor chips 40 without voids even between the first internal solder balls 44. The underfill layer 70 may be formed on the wiring substrate 10 without voids between the first internal solder balls 44. The sealing layer 74 may be formed on both side surfaces and the upper surfaces of the semiconductor chips 40 to seal the semiconductor chips 40.

The lower wiring pads 20 insulated by the lower protective layer 16 and spaced apart from each other are beneath the wiring substrate 10. The plurality of external solder balls 31 are formed on the lower wiring pads 20, respectively.

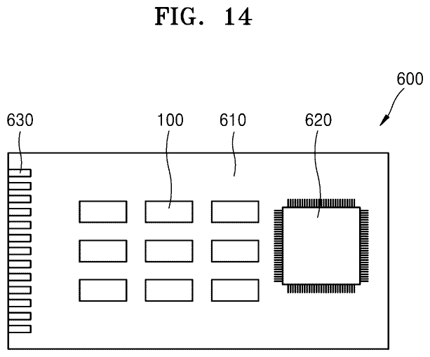

FIG. 14 is a top view schematically illustrating a package module 600 using a semiconductor package according to an embodiment.

Particularly, the package module 600 may include a semiconductor package 100. The semiconductor package 100 may correspond to the semiconductor package EX1 or EX2 according to inventive concepts described above. The package module 600 may include a plurality of semiconductor packages 100 attached to a module substrate 610. The package module 600 may include a semiconductor package 620 attached at one side thereof and an external connection terminal 630 at the other side thereof. The semiconductor package 100 is not limited to the present embodiment and may be applied to various package modules 600.

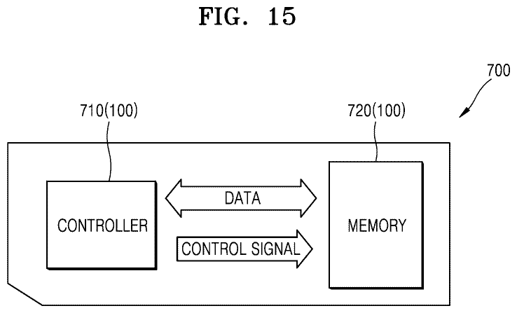

FIG. 15 is a block diagram schematically illustrating a memory card 700 using a semiconductor package according to an embodiment.

Particularly, the memory card 700 may include the semiconductor package 100. The semiconductor package 100 may correspond to the semiconductor package EX1 or EX2 according to inventive concepts described above. The memory card 700 may include various types of cards, e.g., a memory stick card, a smart media (SM) card, a secure digital (SD) card, a mini secure digital (mini SD) card, or a multimedia card (MMC).

The memory card 700 may include a controller 710 and a memory 720. The memory 720 may be flash memory, phase change random access memory (PRAM), or another type of nonvolatile memory. A control signal is transmitted from the controller 710 to the memory 720, and data is exchanged between the controller 710 and the memory 720. For the controller 710 and the memory 720, the semiconductor packages EX1 and EX2 according to inventive concepts described above may be used.

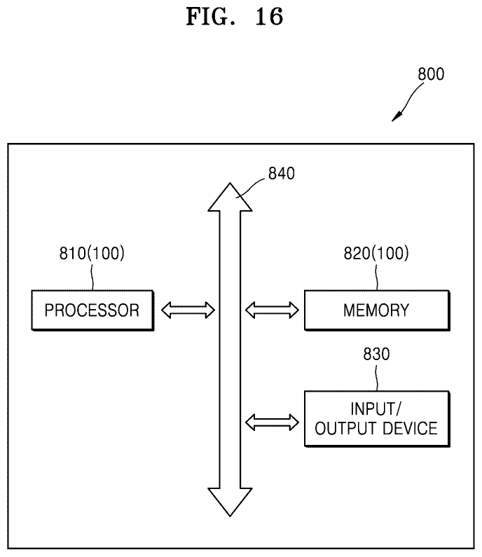

FIG. 16 is a block diagram schematically illustrating an electronic system 800 using a semiconductor package according to an embodiment.

Particularly, the electronic system 800 may include the semiconductor package 100. The semiconductor package 100 may correspond to the semiconductor package EX1 or EX2 according to inventive concepts described above. The electronic system 800 may be a mobile system or a system for transmitting and receiving information. The mobile system may be a personal digital assistant (PDA), a portable computer, a web tablet, a wireless phone, a mobile phone, a digital music player, or a memory card.

The electronic system 800 according to inventive concepts may include a processor 810, a memory 820, and an input/output device 830. For the processor 810 and the memory 820, the semiconductor packages EX1 and EX2 according to inventive concepts described above may be used. The processor 810 exchanges a control signal or data with the memory 820 or the input/output device 830 by using a communication channel 840.

The processor 810 may execute a program and control the electronic system 800. The processor 810 may be, for example, a microprocessor, a digital signal processor, a microcontroller, or a similar device. The input/output device 830 may be used to input or output data of the electronic system 800.

The electronic system 800 may exchange data with an external device, e.g., a personal computer or a network, by being connected to the external device through the input/output device 830. The input/output device 830 may be, for example, a keypad, a keyboard, or a display. The memory 820 may store code and/or data for an operation of the processor 810 and/or store data processed by the processor 810. The processor 810 and the memory 820 may include the semiconductor package 100 according to embodiments.

The communication channel 840 may be a data transmission passage between the electronic system 800 and an external other device. The processor 810, the input/output device 830, and the memory 820 may communicate with each other via the communication channel 840.

One or more of the elements disclosed above may include or be implemented in processing circuitry such as hardware including logic circuits; a hardware/software combination such as a processor executing software; or a combination thereof. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc.

While inventive concepts have been particularly shown and described with reference to embodiments thereof, it will be understood that various changes in form and details may be made therein without departing from the spirit and scope of the following claims.

What is claimed is:

1. A semiconductor package comprising:
a wiring substrate including a core layer, an upper protective layer on an upper surface of the core layer, and a lower protective layer on a lower surface of the core layer,
the wiring substrate including a central through region defining a central through hole that penetrates the upper protective layer, the core layer, and the lower protective layer at a central portion of the wiring substrate;
a semiconductor chip on the wiring substrate and the central through region, the semiconductor chip being connected to the wiring substrate through a plurality of internal solder balls; and
a sealing layer on the wiring substrate and sealing the semiconductor chip, wherein
the sealing layer includes an underfill layer and a molding layer,
the underfill layer is between the plurality of internal solder balls on the wiring substrate,
the molding layer is on side surfaces of the semiconductor chip and an upper surface of the semiconductor chip,
the underfill layer includes a same material as the molding layer,
the central through hole is not filled with a material layer or the central through hole includes an additional underfill layer in a portion of the central through hole adjacent to the upper protective layer.

2. The semiconductor package of claim 1, wherein the central through region is one among a plurality of central through regions in the wiring substrate.

3. The semiconductor package of claim 2, wherein, in a top view, the plurality of central through regions are randomly arranged in the central portion.

4. The semiconductor package of claim 1, further comprising:
a central via wiring layer on an inner wall of the central through hole.

5. The semiconductor package of claim 1, wherein
the plurality of internal solder balls of the semiconductor chip are on a central portion of a lower surface of the semiconductor chip, and
the central through region faces the underfill layer.

6. The semiconductor package of claim 1, wherein the plurality of internal solder balls of the semiconductor chip are disposed at an edge portion of a lower surface of the semiconductor chip, and the central through region corresponds to the underfill layer.

7. The semiconductor package of claim 1, further comprising:
the additional underfill layer, wherein
the central through hole includes the additional underfill layer in the portion of the central through hole adjacent to the upper protective layer.

8. The semiconductor package of claim 1, further comprising:
upper wiring pads in the upper protective layer of the wiring substrate, wherein
the upper wiring pads are respectively connected to the plurality of internal solder balls.

9. The semiconductor package of claim 1, further comprising:
lower wiring pads in the lower protective layer of the wiring substrate, wherein
the lower wiring pads are respectively connected to the plurality of internal solder balls.

10. A semiconductor package comprising:
a wiring substrate including a core layer, an upper protective layer on an upper surface of the core layer, and a lower protective layer on a lower surface of the core layer,
the wiring substrate including a central through region defining a central through hole that penetrates the upper protective layer, the core layer, and the lower protective layer at a central portion of the wiring substrate,
the wiring substrate including a surrounding through region defining a surrounding through hole that penetrates the upper protective layer, the core layer, and the lower protective layer at a surrounding portion of the wiring substrate,
the surrounding portion of the wiring substrate surrounding the central portion of the wiring substrate, and
the surrounding through hole being filled with a material layer;
a semiconductor chip on the wiring substrate, the central through region, and the surrounding through region, the semiconductor chip being connected to the wiring substrate through a plurality of internal solder balls; and
a sealing layer on the wiring substrate and sealing the semiconductor chip, wherein
the sealing layer includes an underfill layer and a molding layer,
the underfill layer is between the plurality of internal solder balls on the wiring substrate,
the molding layer is on side surfaces of the semiconductor chip and an upper surface of the semiconductor chip,
the underfill layer includes a same material as the molding layer, and
the central through hole is not filled with the material layer.

11. The semiconductor package of claim 10, wherein
the central through region is one among a plurality of central through regions in the wiring substrate, and
the surrounding through region is one among a plurality of surrounding through regions in the wiring substrate.

12. The semiconductor package of claim 11, wherein, in a top view, the plurality of central through regions are randomly arranged in the central portion and the plurality of surrounding through regions are randomly arranged in the surrounding portion.

13. The semiconductor package of claim 10, further comprising:
a central via wiring layer on an inner wall of the central through hole.

14. The semiconductor package of claim 10, further comprising:
a surrounding via wiring layer on an inner wall of the surrounding through hole.

15. The semiconductor package of claim 14, wherein the material layer filling the surrounding through hole and the surrounding via wiring layer include same materials.

16. The semiconductor package of claim 10, wherein the material layer filling the surrounding through hole includes a same photosensitive resist layer as the upper protective layer and the lower protective layer.

17. A semiconductor package comprising:
a wiring substrate including a core layer, an upper protective layer on an upper surface of the core layer, a lower protective layer on a lower surface of the core layer, and upper wiring pads in the upper protective layer of the wiring substrate,
the wiring substrate including a central through region defining a central through hole that penetrates the upper protective layer, the core layer, and the lower protective layer at a central portion of the wiring substrate,
the wiring substrate including a surrounding through region defining a surrounding through hole that penetrates the upper protective layer, the core layer, and the lower protective layer at a surrounding portion of the wiring substrate,
the surrounding portion surrounding the central portion of the wiring substrate, and
the surrounding through hole being filled with a material layer;
a plurality of semiconductor chips spaced apart from each other on the wiring substrate, the central through region, and the surrounding through region, the plurality of semiconductor chips including a lowermost semiconductor chip connected to the upper wiring pads of the wiring substrate through a plurality of internal solder balls; and
a sealing layer on the wiring substrate and sealing the plurality of semiconductor chips, the sealing layer including an underfill layer and a molding layer, the underfill layer being between the plurality of internal solder balls connecting the lowermost semiconductor chip to the wiring substrate, the molding layer being on side surfaces of the plurality of semiconductor chips and upper surfaces of the plurality of semiconductor chips, and the underfill layer including a same material as the molding layer, wherein
the central through hole is not filled with the material layer.

18. The semiconductor package of claim 17, further comprising:
a central via wiring layer on an inner wall of the central through hole; and
a surrounding via wiring layer on an inner wall of the surrounding through hole.

19. The semiconductor package of claim 17, wherein
the material layer filling the surrounding through hole includes a same photosensitive resist layer as the upper protective layer and the lower protective layer.

20. The semiconductor package of claim 17, wherein
the plurality of internal solder balls connected to the lowermost semiconductor chip are connected to a central portion of a lower surface of the lowermost semiconductor chip or an edge portion of the lower surface of the lowermost semiconductor chip, and
the central through region faces the underfill layer.
